(19) United States
(12) Patent Application Publication
(10) Pub. No.: US 2010/0078616 A1
(43) Pub. Date: Apr. 1, 2010

(54) NONVOLATILE MEMORY DEVICE AND MANUFACTURING PROCESS THEREOF

(75) Inventors: Akiyoshi Seko, Tokyo (JP); Natsuki Sato, Tokyo (JP); Isamu Asano, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/569,489

(22) Filed: Sep. 29, 2009

(30) Foreign Application Priority Data
Sep. 29, 2008 (JP) 2008-251167

(51) Int. Cl. H01L 47/00; H01L 21/20

(52) U.S. Cl. 257/2; 438/382; 257/E47.001; 257/E21.09

(57) ABSTRACT

A nonvolatile memory device has a first insulating layer, a variable resistance layer provided on the first insulating layer and having a variable resistance material, and a first electrode and second electrode electrically connected with the variable resistance layer. The variable resistance layer has a variable resistance region as a data storing region and a thickness-changing region continuously extending from the variable resistance region and gradually becoming thicker from the variable resistance region.

### REFERENCE TO RELATED APPLICATION

This application is based upon and claims the benefit of the priority of Japanese patent application No. 2008-251167 filed on Sep. 29, 2008, the disclosure of which is incorporated herein in its entirety by reference thereto.

### TECHNICAL FIELD

The present invention relates to a nonvolatile memory device using a variable resistance material as a data storage medium and a method of manufacturing the nonvolatile memory.

### BACKGROUND

Improvement of performance of a solid-state memory device which is formed by a semiconductor integrated circuit art is essential to a highly information-oriented society. As calculation performance of a micro processing unit (MPU) is enhanced, memory capacity for a computer and electronic device continues to increase. It is possible to highly integrate the solid-state memory based on a semiconductor manufacturing art owing to the high mechanical strength because the solid-state memory device has no physically driving portion as included in a magnetic or magneto-optical memory such as a hard disk or laser disk. The solid-state memory is used as not only a cache or main memory for a computer or server but also as an outer storage memory for a mobile device or household electrical appliances and now forms a market of several ten billion dollar scale.

The solid-state memory device is classified into three types by the principle, a SRAM (Static Random Access Memory), a DRAM (Dynamic Random Access Memory) and an EEPROM (Electrically Erasable and Programmable Read Only Memory) such as a flash memory. The SRAM can be operated at the highest speed, but is unsuitable for mass storage because the data can not be stored without power supply and the number of transistors per 1 bit is high. Accordingly, the SRAM is mainly used as a cache in the MPU. The DRAM is mainly used as a main memory in a computer device or household electrical appliances because of easy integration and low cost per 1 bit in spite of lower operation speed than that of the SRAM owing to a refreshing operation. On the other hand, the EEPROM is a nonvolatile memory device capable of storing data without a power supply and is mainly used as a storage memory because a speed of writing and removing data is later than those of the RAMs and relatively large power is required.

Recently, in proportion to rapid growth of the market of the mobile devices, a solid-state memory device interchangeable with the DRAM capable of being operated at higher speed and lower power and further a nonvolatile solid-state memory device having both features of the DRAM and EEPROM are desired to be developed. As a next-generation solid-state memory device, a ReRAM (Resistive Random Access Memory) using a variable resistance material and a FeRAM (Ferroelectric RAM) using a ferroelectric material are attempted to develop. As one of strong candidates of the nonvolatile memory device capable of being operated at the higher speed and lower power, there is a resistive memory device using a phase-change material which is one of the variable resistance materials. This is especially referred as PRAM (Phase Change Random Access Memory). The PRAM is capable of writing data at a speed of 50 ns and has an advantage of high integration because of the simple element structure.

The PRAM has a phase-change material sandwiched between two electrodes and is selectively operated by an active element connected with the phase-change material in series. As the active element, a MOS (Metal-Oxide-Semiconductor) transistor, junction diode, bipolar transistor, or Schottky barrier diode may be used, for example.

Storing and removing data in the PRAM are performed by applying heat energy and thereby generating transition between or among two or more solid-phase states, such as a (poly-) crystalline state and amorphous state, in the phase-change material. The transition between the crystalline state and the amorphous state is recognized as a change of resistance by circuit connection via the electrodes. The heat energy is applied to the phase-change material by applying electrical pulses (voltage or current pulses) between the electrodes and thereby generating the Joule heat in the phase-change material. If the electrical pulses having a heavy current are applied to the phase-change material of the crystalline state in a short time, for example, the phase-change material is heated to a high temperature state close to the melting point, is rapidly cooled, and then becomes the amorphous state (referred to as “reset state”). This operation is generally referred to as “reset operation”. On the other hand, if the electrical pulses having a lower current than that of the reset operation are applied to the reset state in a relatively long time, the phase-change material is heated to the crystallization temperature and then becomes a crystalline state (referred to as “set state”). This operation is referred to as “set operation” against the reset operation.

In the PRAM, there are a PRAM of a vertical type and that of a horizontal type.

The PRAM of the vertical type is disclosed in Patent Document 1 and Non-Patent Document 1, for example. In the PRAM of the vertical type, two electrodes which contact with the phase-change material are provided above and beneath the phase-change material (in the vertical direction). A memory cell array is formed by arranging cells having a phase-change memory element and selective active element in grid-like fashion. The PRAM of the vertical type may easily achieve the high integration and use the cell integration art of the DRAM owing to the structure similar to that of the DRAM. If desired, a memory cell without the selective active element may be made by contriving a memory cell peripheral circuit and the memory cell structure.

The PRAM of the horizontal type is disclosed in Non-Patent Document 2, for example. In the PRAM of the horizontal type, two electrodes which are electrically connected with the phase-change material are provided on both sides of the phase-change region in a planer manner.

### [Patent Document 1]

JP Patent Kokai Publication No. JP-P2007-5785A [Non-Patent Document 1]

Dae-Hwang Kim, et al., Simulation-based comparison of cell design concepts for phase change random access memory, Journal of Nanoscience and Nanotechnology, 7, 298-305 (2007)

### [Non-Patent Document 2]

Martijn H. R. Lankhorst, et al., Low-cost and nanoscale non-volatile memory concept for future silicon chips, Nature Materials, Nature Publishing Group, 4, 347-352 (2005)

### SUMMARY

The entire disclosures of Patent Document 1 and Non-Patent Documents 1-2 are incorporated herein by reference thereto.

The following analysis is given based on a point of view of the present invention.

In the PRAM, it is necessary to rewrite data within a range of a driving current capacity of the selective active element because the PRAM is activated by the selective active element, for example. The phase-change region of the phase-change material in the PRAM (see Non-Patent Document 1, for example) is mainly formed at a part having the highest current density in the time of data writing. In the PRAM of the vertical type, for example, if the phase-change material is not confined in the insulator, the part having the highest current density in which the phase-change material is in contact with a lower electrode generates heat and be mainly phase-changed. If a reset operation is performed from a set state, for example, in order to recognize a state transition of the phase-change material as a change of resistance, it is desired that the phase-change region occupies the contact part with the lower (or upper) electrode in the phase-change material or that the entire current path in the phase-change material always extends in the phase-change region. Accordingly, reduction (scaling-down) of the phase-change region in the phase-change material is effective for the switching operation at the low current within a range of the driving current capacity of the selective active element in the PRAM of the vertical type. In the PRAM of the vertical type, in the case where the phase-change material is not confined in the insulator, the reduction of the contact area of the phase-change material with the electrode is effective for the reduction of the phase-change region. Thereby, power consumption in the time of data writing can be lowered. The phase-change region is a region in which the phase change actually occurs, and is not necessary that the entire volume of the phase-change material is changed in phase.

In the PRAM of the vertical type, the electrode becomes a major heat radiating part when the phase-change material generates Joule heat itself. The reduction of the contact area between the phase-change material and the electrode and the reduction of the cross section of the electrode is therefore effective to suppress the radiant heat from the phase-change material and to efficiently change the phase.

In the PRAM of the vertical type, however, the reduction exceeding the process trend is difficult because the size of the electrode to be connected with the phase-change material is determined based on the minimum processing measure of the lithography step in the ordinary semiconductor manufacturing process. The contact area of the phase-change material with the electrode in the PRAM of the vertical type can not avoid becoming large. The current required for the phase-change becomes high, and therefore the data writing current becomes difficult to be reduced. The minimum processing size denotes a minimum size of the width or gap which is determined and designed by the manufacturing process such as the resolution of photolithography or processing performance of etching.

In the PRAM of the vertical type, there is also a problem of poor heat generation efficiency caused by too a high heat radiation because the phase-change region is close to the electrode in addition to the large contact area of the phase-change material with the electrode.

On the other hand, in the PRAM of the horizontal type, the reduction of the phase-change region is possible by thinning the phase-change material without dependence on the minimum processing size of the lithography step. In the PRAM of the horizontal type, lower current is possible to rewrite data than in the PRAM of the vertical type. Lower resistance contact can be also formed in the interface of the phase-change material and the electrode than in the vertical type because the contact area of the right and left electrodes with the phase-change material can be made relatively larger. The phase-change region can be kept apart from the electrode, and excess heat radiation from the electrode can be restrained at the phase-change because the size of the phase-change region can be reduced by thinning the phase-change material.

However, as described in Non-Patent Document 2, there is a problem that the phase-change material is damaged owing to a change in quality by reactive gas because, in the ordinary PRAM of the horizontal type, partially thinning and minimizing the phase-change region is achieved by dry etching of the lithography method from the upper part of the phase-change material in a wide area. Because there is often a discontinuous thickness changing part (partially thin (small) region and the other region, for example) in the phase-change region, the distribution of an electric field or current density largely changes around the part, and therefore there is also probability that an unequal electric field badly influences the element property.

According to a first aspect of the present invention, there is provided a process for manufacturing a nonvolatile memory device, which includes forming a first insulating layer, and forming a variable resistance layer, which has a variable resistance region as a data storing region, on the first insulating layer without etching a top face of the variable resistance region.

According to a second aspect of the present invention, there is provided a process for manufacturing a nonvolatile memory device, comprising: forming a first insulating layer; forming a groove or recess in the first insulating layer; and forming a variable resistance layer, which has a variable resistance region as a data storing region and a thickness-changing region, on the first insulating layer. The variable resistance region is formed along a bottom surface of the groove or recess. The thickness-changing region gradually becomes thicker from the variable resistance region.

According to a third aspect of the present invention, there is provided a nonvolatile memory device, comprising: a first insulating layer; a variable resistance layer provided on the first insulating layer and having a variable resistance material; and a first electrode and second electrode electrically connected with the variable resistance layer. The variable resistance layer has a variable resistance region as a data storing region and a thickness-changing region continuously extending from the variable resistance region and gradually becoming thicker from the variable resistance region.

The meritorious effects of the present invention are summarized as follows.

The present invention has at least one of the following effects.

According to the present invention, it is unnecessary to use the etching method such as dry etching or wet etching for thinning the variable resistance layer, and thus the variable resistance layer is freed from damages caused by structure default, composition change, or chemical reaction.

The sidewall serves to form the thickness-changing region which gradually becomes thicker, and thus a sudden change of the thickness in the variable resistance layer can be prevented. Thus, partial concentration of an electric field and current in the variable resistance layer can be prevented.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematically cross-sectional view of a PRAM according to a first embodiment of the present invention;

FIG. 2 is a schematically cross-sectional view along the II-II line of FIG. 1;

FIGS. 3 to 3 is a schematic flow chart to explain a process of manufacturing the PRAM according to the first embodiment of the present invention;

FIG. 4 is a schematic flow chart to explain a process of manufacturing the PRAM according to the first embodiment of the present invention;

FIG. 5 is a schematic flow chart to explain a process of manufacturing the PRAM according to the first embodiment of the present invention;

FIG. 6 is a schematic flow chart to explain a process of manufacturing the PRAM according to the first embodiment of the present invention;

FIG. 7 is a schematic flow chart to explain a process of manufacturing the PRAM according to the first embodiment of the present invention; and

FIG. 8 is a schematically cross-sectional view of a PRAM according to a second embodiment of the present invention.

### PREFERRED MODES

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In the present invention, various preferred modes are presented.

Mode 1: As set forth in the first aspect.
Mode 2: As set second in the second aspect.
Mode 3: The process according to Mode 2, further comprises: forming a sidewall along at least a side face of the groove or recess; wherein the variable resistance layer is formed on the first insulating layer and the sidewall so as to form the thickness-changing region along the sidewall.
Mode 4: In the process according to Mode 3, the sidewall has a curved surface which widens the groove or recess in a direction from the bottom of the groove or recess toward a top thereof.
Mode 5: In the process according to Mode 4, a material of the sidewall which is different from a material of the first insulating layer is deposited on the first insulating layer so as to have isotropic step coverage; and the curved surface is formed by etching the material of the sidewall.
Mode 6: In the process according to Mode 2, forming the variable resistance layer does not include etching a top face of variable resistance region to form the variable resistance region.
Mode 7: In the process according to Mode 2, the variable resistance layer is formed by a sputtering method in which a distance between a target material and the first insulating layer and an incident angle of ions to the target material are adjusted so that the variable resistance layer has a thinnest region on the bottom side of the groove or recess.
Mode 8: As set forth in the third aspect.
Mode 9: In the nonvolatile memory device according to Mode 8, the first insulating layer has a groove or recess; and the variable resistance region is formed along a bottom surface of the groove or recess.
Mode 10: In the nonvolatile memory device according to Mode 9, the thickness-changing region is formed along a side face of the groove or recess.
Mode 11: The nonvolatile memory device according to Mode 9, further comprises: a sidewall formed along the side face of the groove or recess; wherein the sidewall has a curved surface to widen the groove or recess in a direction from the bottom of the groove or recess to the upper part of the groove or recess; and the thickness-changing region is formed on the curved surface.
Mode 12: In the nonvolatile memory device according to Mode 8, the variable resistance region in the variable resistance layer has a thickness of 1 nm to 50 nm; and a region other than the variable resistance region in the variable resistance layer has a thickness of 30 nm to 100 nm.
Mode 13: In the nonvolatile memory device according to Mode 8, the variable resistance material includes a phase-change material.
Mode 14: The nonvolatile memory device according to Mode 8, further comprises: a second insulating layer on the variable resistance layer.

A nonvolatile memory device of the present invention and manufacturing process thereof will be explained below giving an example of a PRAM which uses a phase-change material as a variable resistance material.

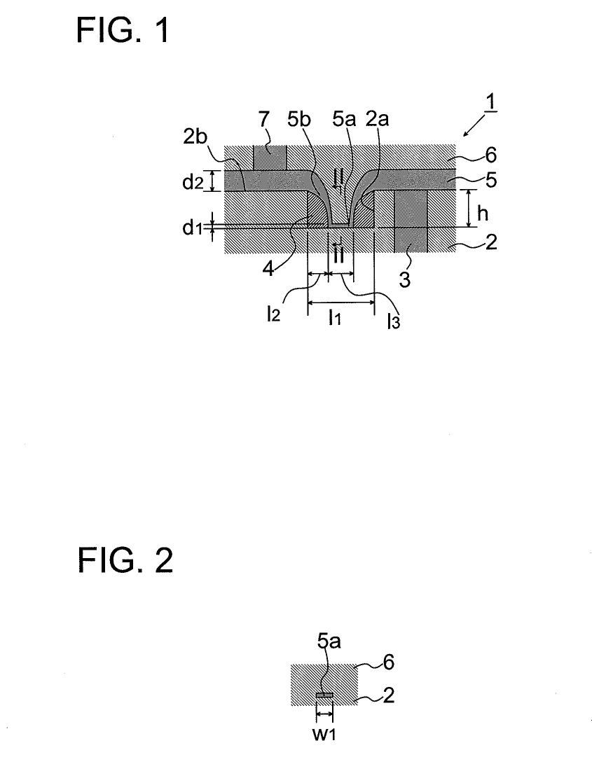

A PRAM according to a first embodiment of the present invention will be explained. FIG. 1 illustrates a schematically cross-sectional view of the PRAM according to the first embodiment of the present invention. FIG. 2 illustrates a schematically cross-sectional view along the II-II line of FIG. 1. The PRAM (nonvolatile memory device) 1 has a first insulating layer 2, a phase-change layer (variable resistance layer) 5 provided on the first insulating layer 2, a second insulating layer 6 provided on the phase-change layer 5, sidewalls 4 provided on the first insulating layer 2 and under the phase-change layer 5, and a first electrode 3 and second electrode 7 both electrically connected with the phase-change layer 5.

The phase-change layer 5 to which an electric current is applied by (across) the first electrode 3 and second electrode 7 has a phase-change region (variable resistance region) 5a which self-generates heat by an electric current and thereby changes the phase. The first electrode 3 and second electrode 7 are electrically connected with the phase-change layer 5 and do not directly contact with the phase-change region 5a.

The first insulating layer 2 has a recess or groove 2a (referred as “recess” below). The phase-change region 5a is formed in the recess 2a. The sidewalls 4 are provided along both side walls of the recess 2a. It is preferred that there is no sidewall 4 on the bottom (surface) of the recess 2a. A side face of the sidewall 4 (a face facing the interior of the recess 2a) has a curved surface. The sidewall 4 has the curved surface to widen the width of the recess 2a. A curvature of the curved surface may be suitably designed corresponding to a desired thickness in each region of the phase-change layer 5. Smaller the curvature of the curved surface of the sidewall 4 becomes, greater the ratio of a thicker region of the phase-change layer 5 to a thinner region is made.

The phase-change layer 5 extends on the first insulating layer 2 and sidewall 4. The phase-change layer 5 has the thinnest part on at the bottom of the recess 2a of the first insulating layer 2, the thinnest part being the phase-change region 5a. On the curved surface of the sidewall 4, the phase-change layer 5 also has a thickness-change region 5b which continuously extends from the phase-change region 5a and gradually becomes thicker from the bottom of the recess 2a toward a top face 2b of the first insulating layer 2 on both sides. On the sidewall 4, the phase-change layer 5 gradually becomes thicker from the lower part to the upper part of the sidewall 4 and has the thickest region on the top face 2b of the first insulating layer 2. The thickness-change region 5b can prevent partial concentration of the current in a region other than the phase-change region 5a because the thickness-change region 5b gradually changes the thickness of the phase-change layer 5.

The length l₁ of the recess 2a is preferably shorter for the minimization and high integration of the element and, for example, may be designed to 40 nm to 500 nm. The difference in level (depth) h of the recess 2a is preferably designed to 30 nm to 100 nm, for example. The length l₂ of one sidewall 4 (width from the side wall on the bottom of the recess 2a) may be designed to 15 nm to 240 nm, for example, in association with the length l₁ of the recess 2a. The distance l₃ between both sidewalls 4 (length of the phase-change region 5a) is preferably designed to 10 nm to 200 nm, for example.

It is preferred that, in the phase-change region 5a, the cross-sectional area of a section perpendicular to the current flow direction (the cross section illustrated in FIG. 2) is enough small so as to promptly phase-change the phase-change region 5a by a low power. On the other hand, it is preferred that, in the phase-change layer 5, the region other than the phase-change region 5a has a cross section greater than that of the phase-change region 5a so as not to increase the resistance. It is therefore preferred that the phase-change region 5a is thinner or narrower than the region other than the phase-change region 5a. The volume of the phase-change region 5a (cross section shown in FIG. 2, especially) is designed so as to write data by a desired power at a desired speed. The phase-change region 5a is designed so as to have an even thickness. The thickness d₁ of the phase-change region 5a may be designed to 1 nm to 50 nm, for example. The thickness d₂ of at least one part of the phase-change layer 5 other than the phase-change region 5a (in FIG. 1, the thickness above the top face 2b of the first insulating layer 2) may be designed to 30 nm to 100 nm, for example. The width w₁ of the phase-change region 5a may be designed to 30 nm to 200 nm, for example. The width of the region other than the phase-change region 5a may be about one time to three times as wide as the width w₁ of the phase-change region 5a.

A material for the phase-change layer 5 may be those having two or more phase states corresponding to temperatures and different electric resistances corresponding to the phase states. As the material for the phase-change layer 5, a chalcogenide material may be used, for example. Chalcogen elements belong to the sixteenth group of the periodic table and indicate sulfur (S), selenium (Se), and tellurium (Te). The chalcogenide material generally indicates a compound including at least one chalcogen element and at least one element among germanium (Ge), tin (Sn) and antimony (Sb). The chalcogenide material may include at least one (one or more) of nitrogen (N), oxygen (O), copper (Cu) and aluminum (Al). As an example, a binary compound such as GaSb, InSb, InSe, Sb₂Te₃ and GeTe, a ternary compound such as Ge₂Sb₂Te₅, InSbTe, GaSeTe, SnSb₂Te₄ and InSbGe, and a quarternary compound such as AgInSbTe, (GeSn)SbTe, GeSb(SeTe) and Te₈₁Ge₁₅Sb₂S₂ are given.

A material for the sidewall 4 may be an insulator or metal. If the insulator is used as the sidewall 4, as explained regarding the manufacturing process below, it is preferred that the material of the sidewall 4 is different from that of the first insulating layer 2 so as to selectively etch the sidewall 4 against the first insulating layer 2. If BPSG (Boro-Phospho silicate glass) is used as the material of the first insulating layer 2, for example, SiN may be used as the material of the sidewall 4.

The first electrode 3 and second electrode 7 are electrically connected with the phase-change layer 5 so as to dispose (sandwich) the phase-change region 5a between (across) the first electrode 3 and the second electrode 7. The first electrode 3 and second electrode 7 may be connected with the phase-change layer 5 in (or from) any direction. Both of the first electrode 3 and second electrode 7 may be formed above or under the phase-change layer 5, for example. In FIG. 1, the first electrode 3 is provided under (beneath) the phase-change layer 5, and the second electrode 7 is provided above the phase-change layer 5. In this example, the first electrode 3 electrically connects the phase-change layer 5 with a lower circuit or selective active element, and the second electrode 7 electrically connects the phase-change layer 5 with a bit line.

In order to phase-change the phase-change region 5a, it is necessary that the current density and electric field of the phase-change region 5a are made highest in the phase-change layer 5. It is preferred that the contact area of the phase-change layer 5 with the first electrode 3 or second electrode 7 is sufficiently large compared to the cross section of the phase-change region 5a shown in FIG. 2 so as to make the interface resistance lower than that of the phase-change region 5a. The contact area of the phase-change layer 5 with the first electrode 3 or second electrode 7 is preferably two to twenty times as large as the cross section of the phase-change region 5a shown in FIG. 2, in a case where an opening to deposit the first electrode 3 or second electrode 7 in the insulating layer has a column shape, the area of the opening may be within a range of 700 nm² to 200,000 nm².

A material for the first electrode 3 and second electrode 7 may be known electrode materials. Titanium (Ti), tantalum (Ta), molybdenum (Mo), niobium (Nb), zirconium (Zr) or tungsten (W), a nitride of any metal of the these metals, or a silicide including any metal or nitride of these metals or nitrides may be used, for example. An alloy including any metal of these metals may be also used. The compound such as nitride and silicide to form the electrode material does not necessarily have stoichiometric ratio. Impurities such as carbon (C) may be added to the electrode material.

The second insulating layer 6 preferably has a thickness of at least 50 nm in order to protect the phase-change layer 5.

A material of the first insulating layer 2 and second insulating layer 6 and material of the insulating sidewall 4 may be any material which is available for the insulating layer. Silicon oxide (SiO₂), silicon nitride (SiN) or the mixture of these materials may be used, for example. An insulating film having a low dielectric constant such as BPSG may be also used. The insulating layer preferably has high atomic density by heat treatment because the higher atomic density the insulating layer has, the higher the heat conduction becomes. The first insulating layer 2 and second insulating layer 6 are preferably of a lower dielectric constant material (such as silicon oxide (SiO₂) or BPSG) in order to suppress parasitic capacity.

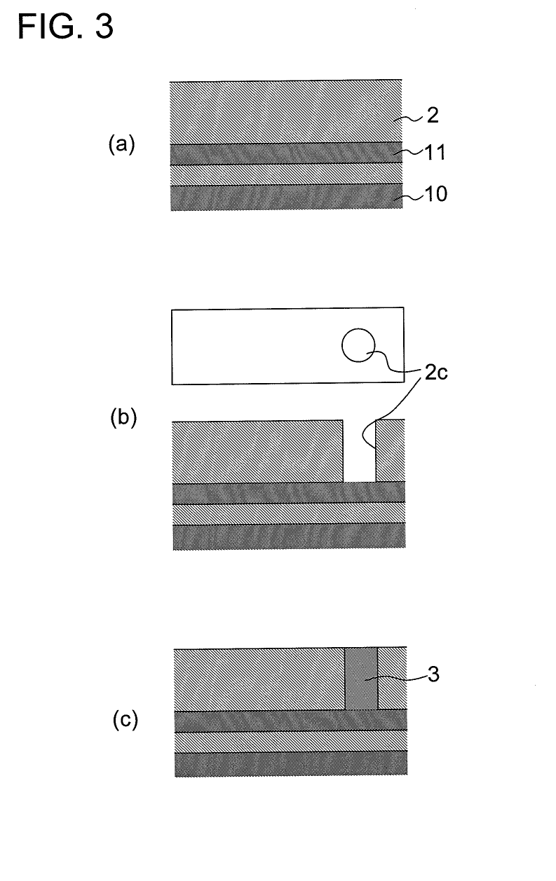

Next, a process of manufacturing the PRAM according to a first embodiment of the present invention will be explained below. FIGS. 3-7 illustrate schematic flow charts to explain a process of manufacturing the PRAM according to the first embodiment of the present invention.

First, a lower circuit layer 11 and first insulating layer 2 are formed on a substrate 10 ((a) of FIG. 3).

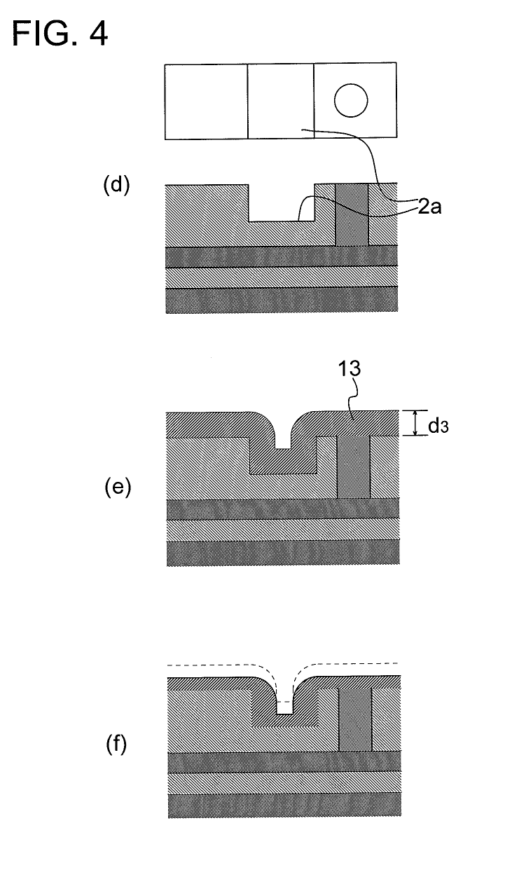

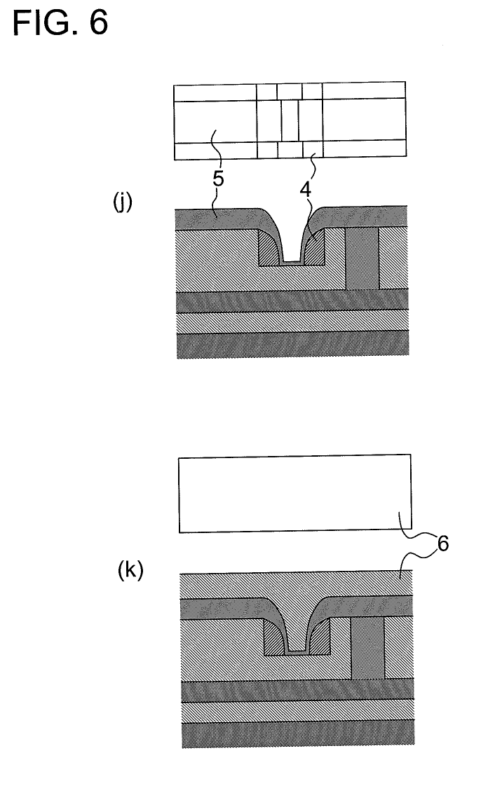

Next, the first insulating layer 2 is etched by a lithography method, for example, so as to expose the lower circuit layer 11, and a through hole 2c designed to form a first electrode 3 is thereby formed ((b) of FIG. 3). In (b) of FIG. 3, the lower figure shows a schematic cross-sectional view, and the upper figure shows a schematic top plain view. In the schematic top plain view, the outer line does not necessarily indicate an end face. The same applies also to (d) of FIG. 4 to (k) of FIG. 6.

Next, a material of a first electrode 3 is deposited into the through hole 2c by a sputtering method, for example. Next, the surface thereof is planarized by the CMP method or etch-back method, for example, to form the first electrode 3 ((c) of FIG. 3).

Next, the first insulating layer 2 is etched by the lithography method to form the recess 2a ((d) of FIG. 4).

Next, a material 13 of the sidewalls 4 which is different from that of the first insulating layer 2 is deposited into a recess 2a by the sputtering method so as to have isotropic step coverage ((e) of FIG. 4). The thickness d₃ of a material 13 of sidewalls 4 is preferably made even against the surface of the first insulating layer 2. The thickness d₃ of the material 13 of the sidewalls 4 is preferably similar to the difference in level (depth) h of the recess 2a and, for example, 30 nm to 100 nm. If the thickness d₃ of the material 13 of the sidewalls 4 be too thinner than the difference in level (depth) h of the recess 2a, the sidewalls 4 having a desired shape can not be formed in the next step because the curvature of the curved surface of the sidewall 4 become too great. On the other hand, if the thickness d₃ of the material 13 of the sidewalls 4 be too thicker than the difference in level (depth) h of the recess 2a, a step of leveling the bottom surface of the recess 2a is required after the formation of the sidewall 4, which in turn brings about a too great curvature of the curved surface of the sidewall 4 becomes too high.

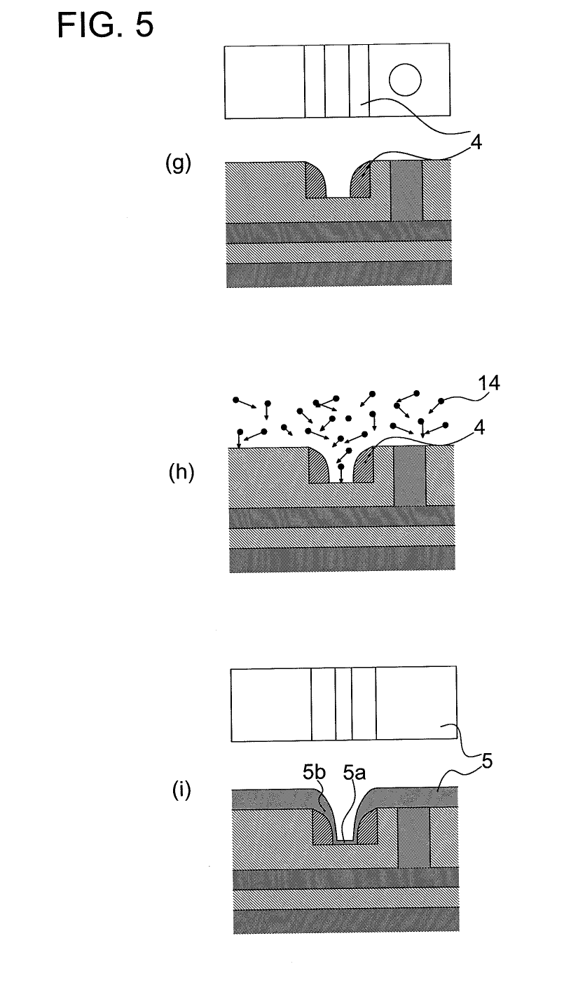

Next, the material of the sidewalls 4 is anisotropically etched, and the sidewalls 4 having the curved surface are thereby formed along both sides of the recess 2a of the first insulating layer 2 ((f) of FIG. 4 and (g) of FIG. 5). (f) of FIG. 4 illustrates an intermediate state of the anisotropic etching. The material of the sidewalls 4 may be etched so as to expose a part of the bottom of the recess 2a of the first insulating layer 2 or to leave the material of the sidewalls 4 on the bottom of the recess 2a. It is preferred that the bottom of the recess 2a is leveled in order to precisely control the cross-sectional shape of the phase-change region 5a.

Next, the material of the phase-change layer 5 is deposited on the first insulating layer 2 by, for example, the sputtering method using a DC magnetron ((h) of FIG. 5). Without the etching process, a thinnest phase-change region 5a is formed on the bottom of the recess 2a, a thickness-change region 5b which is connected with the phase-change region 5a and has a thickness gradually becoming thicker from the phase-change region 5a to the top face 2b of the first insulating layer 2 is formed on the sidewalls 4, and the phase-change layer 5 has a thickest region on the top face 2b of the first insulating layer 2 ((i) of FIG. 5).

The principle will be explained using (h) of FIG. 5. In a space where material clusters 14 of the phase-change layer 5 travel from leaving a target to reaching the surface of the first insulating layer 2, if the sputter condition is controlled so that the density of the material clusters 14 of the phase-change layer 5 becomes high, the travelling direction and energy (vector) of the material cluster 14 become a dispersed (random) state just before reaching the face as shown in (h) of FIG. 5 because of continuous dispersion. The kinetic energy also becomes lower than that near the target due to the dispersion. On the top face (flat face) 2b of the first insulating layer 2, the speed of the film forming becomes higher because the material clusters 14 are supplied from every direction. On the other hand, at a point where the sidewalls 4 obstruct the supply of the material clusters 14 in the horizontal direction, like the bottom of the recess 2a, the speed of the film forming becomes lower because only the material clusters 14 having a vector in the vertical direction reach. On the sidewalls 4, the speed of the film forming in the upper part becomes higher because an amount of supply of the material clusters 14 are relatively large, whereas the speed of the film forming in the lower part becomes lower because the supply of the material clusters 14 from the sides is obstructed by the sidewalls 4. Based on this principle, the thickness of the phase-change layer 5 can gradually thin down from on the top face 2b to on the bottom of the recess 2a along on the sidewalls 4. As the sputtering condition, an incident angle of ions is made larger by making the distance between the target material and the substrate longer, and the difference between the thickness on the bottom of the recess 2a and that on the other region can be thereby made enough large. The difference in the thickness can be easily made larger by weakening the magnetic field of the magnetron and thickening the density of argon in order to relieve the collision energy of argon to the target. For the film forming of the phase-change layer 5, a bipolar or multipolar sputter using DC or a magnetron sputter, bipolar sputter or multipolar sputter using RF radical may be used other than the DC magnetron sputter.

Next, the deposited material of the phase-change layer 5 is etched by the lithography method to a linear phase-change layer 5 ((j) of FIG. 6). The width of the line is preferably as thin as possible. A material (silicon oxide (SiO₂), for example) which is available for a protective layer of the variable resistance material may be used as a hard mask. This can omit a step of removing the hard mask because the hard mask may be used as a second insulating layer 6. This can also reduce any damage given to the phase-change layer 5 because it is unnecessary to etch the top face of phase-change layer 5.

Next, on the top and the sides of (i.e., overall over) the phase-change layer 5, the second insulating layer 6 as the protective insulating layer is deposited by, for example, the CVD method, and the surface thereof is planarized by, for example, the CMP method ((k) of FIG. 6).

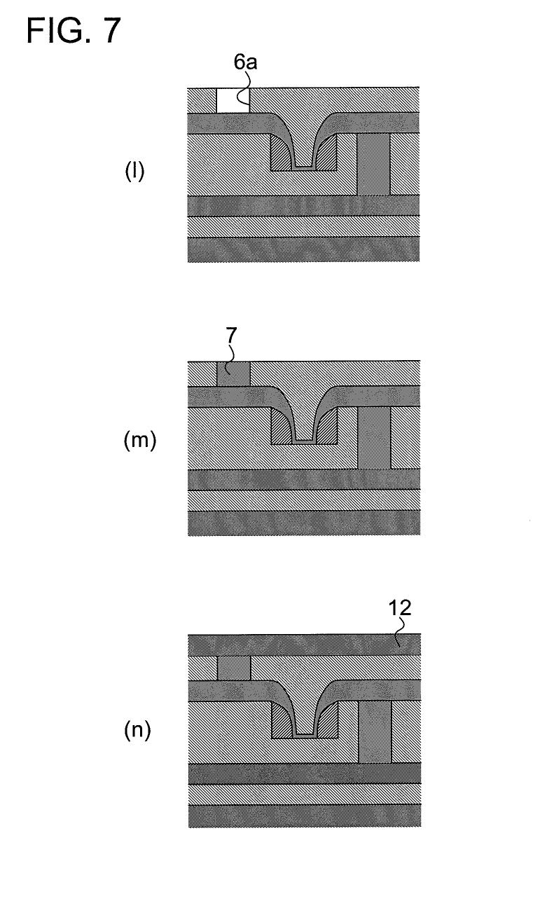

In order to form a through hole 6a for forming a second electrode 7, the second insulating layer 6 at a position other than on the phase-change region 5a is etched by the lithography method so as to expose the phase-change layer 5 ((l) of FIG. 7).

Next, a material of the second electrode 7 is deposited into the through hole 6a by, for example, the sputtering method, and the surface thereof is planarized by, for example, the CVD method ((m) of FIG. 7).

Next, the bit line 12 is formed so as to be electrically connected with the second electrode 7 ((n) of FIG. 7). Thus, the PRAM is manufactured.

According to the manufacturing process of the present invention, an enhanced reliability of the phase-change region can be achieved because the phase-change region can be formed without the etching of the top face of the phase-change layer.

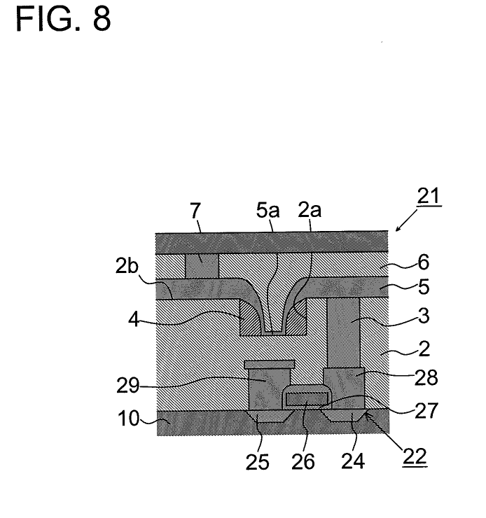

Next, a PRAM according to a second embodiment of the present invention will be explained below. FIG. 8 illustrates a schematically cross-sectional view of the PRAM according to the second embodiment of the present invention. In the first embodiment, a mode without selective active element is explained, whereas, in the second embodiment, a mode with a selective active element will be explained.

A PRAM 21 has a MOS transistor 22 as a selective active element. The MOS transistor 22 has a first diffusion layer 24, a second diffusion layer 25, a gate electrode 26, and a gate insulating film 27. A first contact 28 is electrically connected with the first diffusion layer 24, and a second contact 29 is electrically connected with the second diffusion layer 25. In the first embodiment, the first electrode is electrically connected with the lower circuit, whereas, in the present embodiment, the first electrode 3 is electrically connected with the first diffusion layer 24 through the first contact 28. An explanation other than the above is omitted because the other formulation is the same as the formulation according to the first embodiment.

An explanation of a manufacturing process of the PRAM 21 is also omitted because the process is the same as the process according to the first embodiment.

Although the above embodiment is explained by giving an example of the phase-change material as the variable resistance material, the variable resistance material in the present invention is not limited to the phase-change material. As the variable resistance material, for example, titanium oxide (TiO₂), nickel oxide (NiO), or copper oxide (CuO) may be used, or a variable resistance material mainly using metal oxide which includes two or more elements may be used.

Although the prevent invention is explained based on the above embodiments, the present invention is not limited to the above embodiments, and may include any modification, change and improvement to the embodiment within the scope of the present invention. Within the scope of the present invention, various combinations, displacements and selections of disclosed elements are available.

A further problem, object and embodiment of the present invention become clear from the entire disclosure of the present invention including claims.

What is claimed is:

1. A process for manufacturing a nonvolatile memory device comprising:
forming a first insulating layer; and
forming a variable resistance layer, which has a variable resistance region as a data storing region, on said first insulating layer without etching a top face of said variable resistance region.

2. A process for manufacturing a nonvolatile memory device comprising:
forming a first insulating layer;
forming a groove or recess in said first insulating layer; and
forming a variable resistance layer, which has a variable resistance region as a data storing region and a thickness-changing region, on said first insulating layer, said variable resistance region being formed along a bottom surface of said groove or recess, said thickness-changing region gradually becoming thicker from said variable resistance region.

3. The process according to claim 2, further comprising:
forming a sidewall along at least a side face of said groove or recess; wherein
said variable resistance layer is formed on said first insulating layer and said sidewall so as to form said thickness-changing region along said sidewall.

4. The process according to claim 3, wherein
said sidewall has a curved surface which widens said groove or recess in a direction from the bottom of said groove or recess toward a top thereof.

5. The process according to claim 4, wherein
a material of said sidewall which is different from a material of said first insulating layer is deposited on said first insulating layer so as to have isotropic step coverage; and
said curved surface is formed by etching the material of said sidewall.

6. The process according to claim 2, wherein
forming said variable resistance layer does not include etching a top face of variable resistance region to form said variable resistance region.

7. The process according to claim 2, wherein
said variable resistance layer is formed by a sputtering method in which a distance between a target material and said first insulating layer and an incident angle of ions to the target material are adjusted so that said variable resistance layer has a thinnest region on the bottom side of said groove or recess.

8. A nonvolatile memory device comprising:
a first insulating layer;
a variable resistance layer provided on said first insulating layer and having a variable resistance material; and
a first electrode and second electrode electrically connected with said variable resistance layer; wherein
said variable resistance layer has a variable resistance region as a data storing region and a thickness-changing region continuously extending from said variable resistance region and gradually becoming thicker from said variable resistance region.

9. The nonvolatile memory device according to claim 8, wherein
said first insulating layer has a groove or recess; and
said variable resistance region is formed along a bottom surface of said groove or recess.

10. The nonvolatile memory device according to claim 9, wherein
said thickness-changing region is formed along a side face of said groove or recess.

11. The nonvolatile memory device according to claim 9, further comprising:
a sidewall formed along the side face of said groove or recess; wherein
said sidewall has a curved surface to widen said groove or recess in a direction from the bottom of said groove or recess to the upper part of said groove or recess; and
said thickness-changing region is formed on said curved surface.

12. The nonvolatile memory device according to claim 8, wherein
said variable resistance region in said variable resistance layer has a thickness of 1 nm to 50 nm; and
a region other than said variable resistance region in said variable resistance layer has a thickness of 30 nm to 100 nm.

13. The nonvolatile memory device according to claim 8, wherein
said variable resistance material includes a phase-change material.

14. The nonvolatile memory device according to claim 8, further comprising:
a second insulating layer on said variable resistance layer.
